(19) United States
(12) Patent Application Publication
(10) Pub. No.: US 2025/0296268 A1
(43) Pub. Date: Sep. 25, 2025

(54) TEMPLATE WITH SACRIFICIAL LAYER, METHOD OF MANUFACTURING TEMPLATE WITH SACRIFICIAL LAYER, METHOD OF REMANUFACTURING TEMPLATE WITH SACRIFICIAL LAYER, AND METHOD OF MANUFACTURING SEMICONDUCTOR DEVICE

(71) Applicant: Kioxia Corporation, Tokyo (JP)

(72) Inventor: Kasumi OKABE, Nagoya Aichi (JP)

(73) Assignee: Kioxia Corporation, Tokyo (JP)

(21) Appl. No.: 18/821,516

(22) Filed: Aug. 30, 2024

(30) Foreign Application Priority Data
Mar. 21, 2024 (JP) 2024-045360

(51) Int. Cl. B29C 43/36; B29C 33/38; B29C 43/02; B29C 43/50; B29L 31/34; G03F 7/00; H01L 21/027

(52) U.S. Cl. CPC B29C 43/36; B29C 33/3857; B29C 43/021; B29C 43/50; G03F 7/0002; B29L 2031/3406; H01L 21/027

(57) ABSTRACT

According to one embodiment, a method of manufacturing a template includes forming a sacrificial layer on a substrate. A first pattern is formed on a surface of the sacrificial layer opposite to a surface of the sacrificial layer in contact with the substrate. A replication material layer is formed on a surface of the first pattern of the sacrificial layer. A surface of the replication material layer opposite to a surface of the replication material layer in contact with the sacrificial layer is bonded to a template substrate. The replication material layer is cured to form a replication portion having a second pattern corresponding to the first pattern. The substrate is removed from the sacrificial layer to provide the template including the template substrate and the replication portion.

### CROSS-REFERENCE TO RELATED APPLICATION

This application is based upon and claims the benefit of priority from Japanese Patent Application No. 2024-045360, filed Mar. 21, 2024, the entire contents of which are incorporated herein by reference.

### FIELD

Embodiments described herein relate generally to a template with a sacrificial layer, a method of manufacturing a template with a sacrificial layer, a method of remanufacturing a template with a sacrificial layer, and a method of manufacturing a semiconductor device.

### BACKGROUND

A template used in an imprint process has a pattern including uneven portion. Before the template is used in the imprint process, a surface having a desired pattern is peeled off from a template substrate that is a base, and in this case, a pattern defect may occur.

Examples of related art include JP-A-2019-149488, JP-A-2021-150461, and JP-A-2014-120584.

### DESCRIPTION OF THE DRAWINGS

FIGS. 1A to 1D are an upper surface view and cross-sectional views schematically showing an example of a configuration of a template according to a first embodiment.

FIGS. 2A to 2D are cross-sectional views schematically showing an example of a procedure of a method of manufacturing a first template portion of the template according to the first embodiment.

FIGS. 3A to 3E are cross-sectional views schematically showing an example of a procedure of a method of manufacturing a second template portion of the template according to the first embodiment.

FIGS. 4A to 4F are cross-sectional views schematically showing an example of a procedure of a method of manufacturing the template according to the first embodiment.

FIGS. 5A to 5H are cross-sectional views schematically showing an example of a procedure of a method of manufacturing a third template portion of a template according to a second embodiment.

FIGS. 6A to 6F are cross-sectional views schematically showing an example of a procedure of a method of manufacturing the template according to the second embodiment.

FIGS. 7A to 7D are an upper surface view and cross-sectional views schematically showing an example of a configuration of a template according to a third embodiment.

FIG. 8 is a diagram showing an example of movement of a template according to a fourth embodiment.

FIGS. 9A to 9F are cross-sectional views schematically showing an example of a procedure of a method of manufacturing a semiconductor device according to a fifth embodiment.

FIG. 10A to 10D are cross-sectional views schematically showing an example of a procedure of a method of remanufacturing a template according to the fifth embodiment.

FIG. 11 is a flowchart showing an example of a procedure of a method of remanufacturing the template according to the fifth embodiment.

### DETAILED DESCRIPTION

Embodiments provide a template with a sacrificial layer, a method of manufacturing a template with a sacrificial layer, a method of remanufacturing a template with a sacrificial layer, and a method of manufacturing a semiconductor device, which are capable of reducing a pattern defect of a template.

In general, according to one embodiment, a method of manufacturing a template with a sacrificial layer includes forming a sacrificial layer on a substrate and forming a first pattern on a surface of the sacrificial layer opposite to a surface of the sacrificial layer in contact with the substrate. In addition, the method includes forming a replication material layer on the surface of the first pattern in the sacrificial layer, and bonding a surface of the replication material layer opposite to a surface of the replication material layer in contact with the sacrificial layer to a template substrate with an adhesive film sandwiched therebetween. The method includes peeling off the substrate and the sacrificial layer after curing the replication material layer to form a replication portion having a second pattern corresponding to the first pattern.

Hereinafter, embodiments of the present disclosure will be described with reference to the drawings. The present embodiment does not limit the present disclosure. The drawings are schematic or conceptual, and the ratio of each part is not necessarily the same as the actual one. In this specification and drawings, the same elements as those described above with respect to the above-mentioned drawings are designated by the same reference numerals, and detailed description thereof will be omitted as appropriate.

### First Embodiment

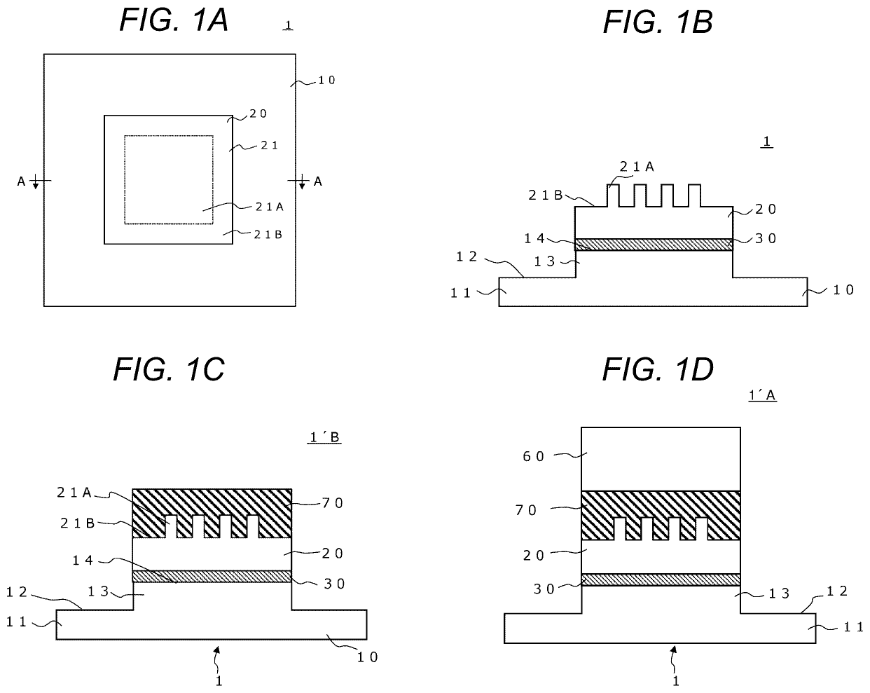

FIGS. 1A to 1D are views schematically showing an example of a configuration of a template 1 according to a first embodiment. FIG. 1A is an upper surface view of the template 1, and FIG. 1B is a cross-sectional view taken along line A-A in FIG. 1A. In addition, FIG. 1C is a cross-sectional view taken along line A-A, which schematically shows an example in which a sacrificial layer 70 to be described later is formed on the template 1, and FIG. 1D is a cross-sectional view taken along line A-A, which schematically shows an example in which the sacrificial layer 70 and a second substrate 60 to be described later are formed on the template 1.

The template 1 includes a template substrate 10, a replication portion 20, and an adhesive film 30.

The template substrate 10 has a rectangular base portion 11 and a mesa portion 13 provided in a vicinity of a center of a base portion first surface 12 in the base portion 11. A plurality of mesa portions 13 may be provided, or the mesa portion 13 may not be provided. When the mesa portion 13 is not provided, the adhesive film 30 to be described later is in contact with the base portion first surface 12. The template substrate 10 may be made of a material capable of transmitting ultraviolet light, and may contain, for example, quartz glass.

The base portion 11 has, for example, a rectangular flat plate-shaped structure. The mesa portion 13 is provided in the vicinity of the center of the base portion first surface 12. The base portion 11 contains, for example, quartz glass.

The mesa portion 13 contains, for example, quartz glass and has a rectangular flat plate-shaped structure. In addition, for example, the mesa portion 13 has a shape that protrudes from a substantially center of the base portion first surface 12 and is a rectangle that is smaller than the base portion 11 in upper surface view. The mesa portion 13 protrudes from the base portion first surface 12, and a mesa portion first surface 14, which is a surface of the mesa portion 13 opposite to a surface of the mesa portion 13 in contact with the base portion first surface 12, is in contact with the adhesive film 30 to be described later. The base portion 11 and the mesa portion 13 may be formed integrally with each other or may be formed separately. Further, the plurality of mesa portions 13 may be provided.

When the plurality of mesa portions 13 are provided, a mesa portion provided in the vicinity of the center of the base portion first surface 12 is referred to as a first mesa portion, and a mesa portion provided in a vicinity of a center of the surface opposite to the surface of the first mesa portion in contact with the base portion first surface 12 is referred to as a second mesa portion. At this time, the second mesa portion may have, for example, a rectangular flat plate-shaped structure, and a size of the second mesa portion may be smaller than a size of the first mesa portion, when the second mesa portion is compared with the first mesa portion. That is, the second mesa portion may have a smaller rectangle than that of the first mesa portion in upper surface view.

The replication portion 20 has a pattern surface 21 on a surface opposite to a surface in contact with the adhesive film 30 to be described later. The pattern surface 21 has an uneven pattern in contact with a resist on a workpiece (not shown) during an imprint process. The pattern surface 21 may be provided with a rectangular pattern arrangement region 21A and a frame-shaped mark arrangement region 21B provided on an outer periphery of the pattern arrangement region 21A in upper surface view. For example, a pattern such as a device and wiring to be formed on the workpiece is disposed in the pattern arrangement region 21A. For example, a mark such as an alignment mark for performing position alignment with the workpiece is disposed in the mark arrangement region 21B.

As the replication portion 20, for example, a replication material 20′ cured by ultraviolet light, heat, or the like to enter the replication portion 20 may be used. At this time, the replication material 20′ to be cured by ultraviolet light is, for example, a transparent resin such as an acrylic, an epoxy, a polyamide, or a polyimide containing an ultraviolet light polymerization initiator. The replication material 20′ contains a photocurable material having a reactive group for curing by ultraviolet light. For example, as the reactive group for curing by ultraviolet light, the material is a material containing a photo-radical polymerizable group having at least one reactive moiety selected from an acryloyl group, a methacryloyl group, and a vinyl ether group, or a photo-cation polymerizable group having at least one reactive moiety selected from an epoxy group and an oxetanyl group. When a material that reacts with and is cured by ultraviolet light is used as the replication material 20′, the replication portion 20 hardly shrinks during the curing.

In addition to the above-described photocurable material containing the ultraviolet light polymerization initiator, a resin that reacts with heat to be cured may be used as the replication material 20′. A thermosetting resin is, for example, a novolac resin or a vinyl resin. When the replication portion 20 contains a thermosetting resin, the replication material 20′ contains a reactive group for curing by heat and does not contain a photocurable material. When a thermosetting resin is used, it is necessary to pre-calculate a shrinkage rate before curing, because the replication portion 20 may shrink during the curing.

The adhesive film 30 is provided between the mesa portion first surface 14 and a surface opposite to a surface on which the pattern surface 21 of the replication portion 20 is provided. The template substrate 10 and the replication portion 20 are in close contact with each other with the adhesive film 30 sandwiched therebetween.

In order to impart adhesiveness, for example, a material containing molecules bonded by hydrogen bonding or covalent bonding between the template substrate 10 and the replication portion 20, is used as the adhesive film 30. The adhesive film 30 may contain a reactive group for bonding to the replication portion 20 and a reactive group for bonding to the template substrate 10.

As described above, the replication portion 20 contains a reactive group for curing. For example, when the replication portion 20 is a material having a photo-radical polymerizable group, a material containing a photo-radical polymerizable group is shown as an example, as a reactive group for bonding to the replication portion 20. In addition, when the replication portion 20 is a material having a photo-cation polymerizable group, a material containing a photo-cation polymerizable group is shown as an example, as a reactive group for bonding to the replication portion 20.

In addition, as the reactive group contained in the adhesive film 30, when the template substrate 10 contains quartz glass, it is possible that a silane coupling agent is shown as an example, to bond to the template substrate 10. Examples of such a silane coupling agent contain monoalkoxysilanes, dialkoxysilanes, trialkoxysilanes, monochlorosilanes, dichlorosilanes, and trichlorosilanes. Therefore, the adhesive film 30 contains, for example, a silane coupling agent having a photo-radical polymerizable group or a silane coupling agent having a photo-cation polymerizable group.

As such the adhesive film 30, for example, 3-(trimethoxysilyl)propyl acrylate, 3-[diethoxy(methyl)silyl]propyl methacrylate, 3-(trimethoxysilyl)propyl methacrylate, 3-[tris(trimethylsilyloxy)silyl]propyl methacrylate, 3-[dimethoxy(methyl)silyl]propyl methacrylate, 3-(methoxydimethylsilyl)propyl acrylate, 3-(triethoxysilyl)propyl methacrylate, 3-(triallylsilyl)propyl acrylate, 3-(triallylsilyl)propyl methacrylate, diethoxy(3-glycidyloxypropyl)methylsilane, 3-glycidyloxypropyltrimethoxysilane, 3-glycidyloxypropyl(dimethoxy)methylsilane, [8-(glycidyloxy)-n-octyl]trimethoxysilane, or triethoxy(3-glycidyloxypropyl)silane may be used.

For example, when 3-(trimethoxysilyl)propyl acrylate is used as the adhesive film 30, the trimethoxysilyl group contained in the adhesive film 30 is bonded to the template substrate 10 containing quartz glass by a silane coupling reaction. In addition, the acryloyl group contained in the adhesive film 30 is bonded to the replication portion 20 having a photo-radical polymerizable group by a photopolymerization reaction. In this way, it is possible to allow the template substrate 10 and the replication portion 20 to be firmly in close contact with each other by the adhesive film 30.

The sacrificial layer 70 is formed on the pattern surface 21 in the replication portion 20. At this time, the sacrificial layer 70 may have a thickness that covers a projection portion of the pattern surface 21. That is, the thickness of the sacrificial layer 70 may be greater than a height of the projection portion of the pattern surface 21 in a stacking direction.

As the sacrificial layer 70, a sacrificial material 70′ cured by ultraviolet light, heat, or the like to enter the sacrificial layer 70 may be used, or the same material with the material shown as an example as the replication material 20′ may be used. Meanwhile, it is preferable for the sacrificial layer 70 to use the sacrificial material 70′ having a higher etching rate than that of the replication portion 20, with respect to a material (an etching agent or the like) used for etching to remove the sacrificial layer 70 to be described later from a first template portion 50 and the replication portion 20.

The second substrate 60 is formed on a surface opposite to a surface in contact with the pattern surface 21 in the sacrificial layer 70. The second substrate 60 is, for example, a silicon substrate.

As shown in FIG. 1C, a template 1′B with a sacrificial layer may include the template 1 and the sacrificial layer 70. Hereinafter, the template 1′B with a sacrificial layer will be abbreviated and referred to as the template 1′B. In addition, also in FIG. 1D, a template 1′A with a sacrificial layer and a substrate may include the template 1, the sacrificial layer 70, and the second substrate 60. Hereinafter, the template 1′A with a sacrificial layer and a substrate will be abbreviated and referred to as the template 1′A.

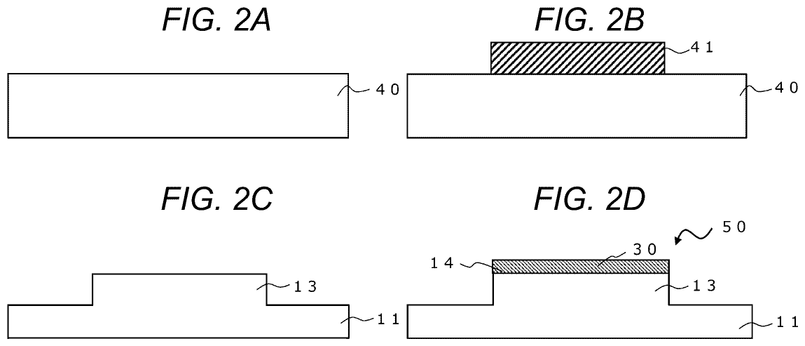

FIGS. 2A to 4F are cross-sectional views schematically showing an example of a procedure of a method of manufacturing the template 1 according to the first embodiment. Here, a circumstance when the adhesive film 30 and the replication material 20′ are materials containing a photo-radical polymerizable group will be described.

FIGS. 2A to 2D are cross-sectional views showing an example of a procedure of a method of manufacturing the first template portion 50. As shown in FIG. 2A, first, a first substrate 40 having a quadrangular shape in cross section is prepared as a starting material. Next, as shown in FIG. 2B, a patterned resist 41 covering a region corresponding to the mesa portion 13 is formed on the first substrate 40. The first substrate 40 is a material capable of transmitting, for example, ultraviolet light, and may be quartz glass. Then, as shown in FIG. 2C, the first substrate 40 is etched by wet etching using the patterned resist 41 to form the mesa portion 13. In the first substrate 40, a portion remaining after etching other than the mesa portion 13 is the base portion 11. In this way, the template substrate 10 including the base portion 11 and the mesa portion 13 is formed. After the mesa portion 13 is formed, the remaining patterned resist 41 is removed.

In FIG. 2D, the adhesive film 30 having a photo-radical polymerizable group is formed on the mesa portion first surface 14 of the formed mesa portion 13 by a film forming method such as a vapor deposition method. For example, a circumstance when the adhesive film 30 contains 3-(trimethoxysilyl)propyl acrylate described above will be described. When the adhesive film 30 is evaporated on the template substrate 10, the trimethoxysilyl group is bonded to the template substrate 10 containing quartz glass by a silane coupling reaction. By this reaction, the adhesive film 30 is formed in a form in which the acryloyl group is directed outward. At this time, the template substrate 10 and the adhesive film 30 are referred to as the first template portion 50.

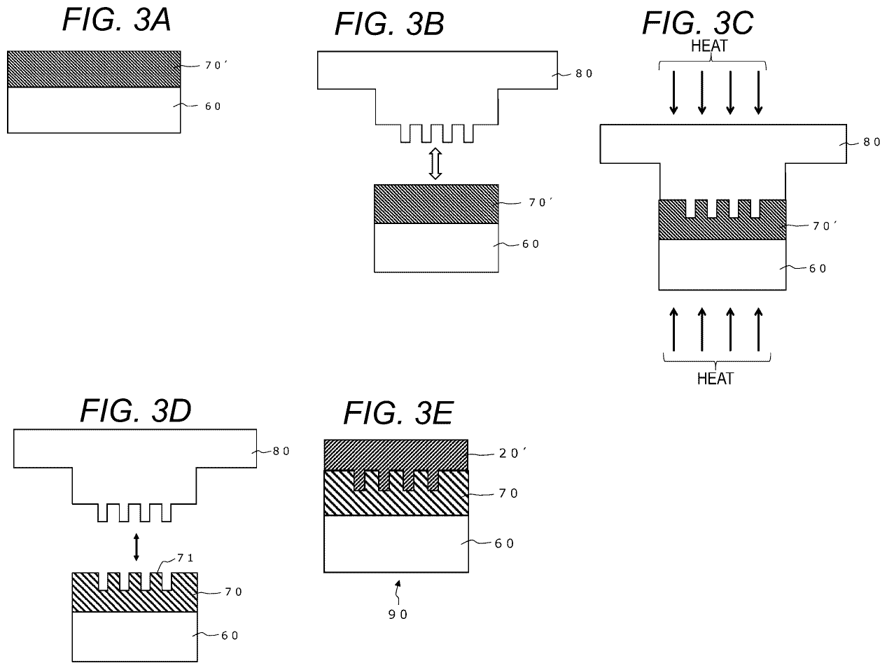

FIGS. 3A to 3E are cross-sectional views showing an example of a method of manufacturing a second template portion 90. FIGS. 3A to 3E show an example of a method of manufacturing the replication portion 20.

As shown in FIG. 3A, first, the sacrificial material 70′ is formed on the second substrate 60. The second substrate 60 is, for example, a silicon substrate. The sacrificial material 70′ is formed by, for example, a spin coating method or a sputtering method. The sacrificial material 70′ may use a material cured by ultraviolet light or heat. When the sacrificial material 70′ is cured by ultraviolet light or heat, after the curing, the sacrificial material 70′ enters the sacrificial layer 70.

For example, the same material with the material shown as an example as the replication material 20′ may be used as the sacrificial material 70′. Meanwhile, it is preferable for the sacrificial layer 70 to use the sacrificial material 70′ having a higher etching rate than that of the replication portion 20, with respect to a material used for etching to remove the sacrificial layer 70 to be described later from the first template portion 50 and the replication portion 20. In addition, it is preferable that the height of the sacrificial layer 70 in the stacking direction is higher than a height of a recess portion in a pattern formed in the sacrificial layer 70.

For example, when the sacrificial material 70′ is a material cured by ultraviolet light, the sacrificial material 70′ may be a transparent resin such as an acrylic, an epoxy, a polyamide, or a polyimide containing an ultraviolet light polymerization initiator. The sacrificial material 70′ contains a photocurable material having a reactive group for curing by ultraviolet light. For example, as the reactive group cured by ultraviolet light, the material is a material containing a photo-radical polymerizable group having at least one reactive moiety selected from an acryloyl group, a methacryloyl group, and a vinyl ether group, or a photo-cation polymerizable group having at least one reactive moiety selected from an epoxy group and an oxetanyl group. When the material that reacts with and is cured by ultraviolet light is used as the sacrificial material 70′, the sacrificial layer 70 hardly shrinks during the curing.

In addition to the above-described photocurable material containing the ultraviolet light polymerization initiator, a resin that reacts with heat to be cured may be used as the sacrificial material 70′. A thermosetting resin is, for example, a novolac resin or a vinyl resin. When the sacrificial layer 70 contains a thermosetting resin, the sacrificial material 70′ contains a reactive group for curing by heat and does not contain a photocurable material. When a thermosetting resin is used, it is necessary to pre-calculate a shrinkage rate before curing, because the sacrificial layer 70 may shrink during the curing. When a thermosetting resin is used, while a shrinkage rate is in consideration, the sacrificial material 70′ is formed such that the height of the sacrificial layer 70 in the stacking direction is higher than the height of the recess portion of a pattern formed on the sacrificial layer 70 in the stacking direction.

Alternatively, a material capable of maintaining a shape without being cured by ultraviolet light or heat may be used as the sacrificial material 70′. The material capable of maintaining a shape has a hardness such that a pattern is maintainable even after a master template 80 is peeled off when the pattern is formed on the sacrificial material 70′ in a step described later. In this case, it is not necessary to cure the sacrificial material 70′ with ultraviolet light or heat, and the sacrificial material 70′ also functions as the sacrificial layer 70.

Hereinafter, a novolac resin having a reactive moiety cured by heat will be described as an example of the sacrificial material 70′ and the sacrificial layer 70.

As shown in FIGS. 3B and 3C, the master template 80 is pressed against the sacrificial material 70′ after position alignment. The master template 80 has the same pattern as an uneven pattern formed on the pattern surface 21 in the replication portion 20. While the master template 80 is pressed against the sacrificial material 70′, the sacrificial material 70′ is heated to be cured.

As shown in FIG. 3D, the sacrificial material 70′ is heated to be cured to enter the sacrificial layer 70. After the sacrificial layer 70 is formed, when the master template 80 is removed, a patterned resist 71 is formed on an upper surface of the sacrificial layer 70. The patterned resist 71 is a pattern corresponding to the uneven pattern formed on the pattern surface 21 in the replication portion 20.

Next, as shown in FIG. 3E, the replication material 20′ having a liquid state photo-radical polymerizable group is formed on an entire surface of the sacrificial layer 70 by a spin coating method. The replication material 20′ is formed on the entire surface of the sacrificial layer 70 with a substantially uniform thickness while a recess portion of the sacrificial layer 70 is embedded with the replication material 20′. The second substrate 60, the sacrificial layer 70, and the replication material 20′ (or the replication portion 20) are referred to as the second template portion 90.

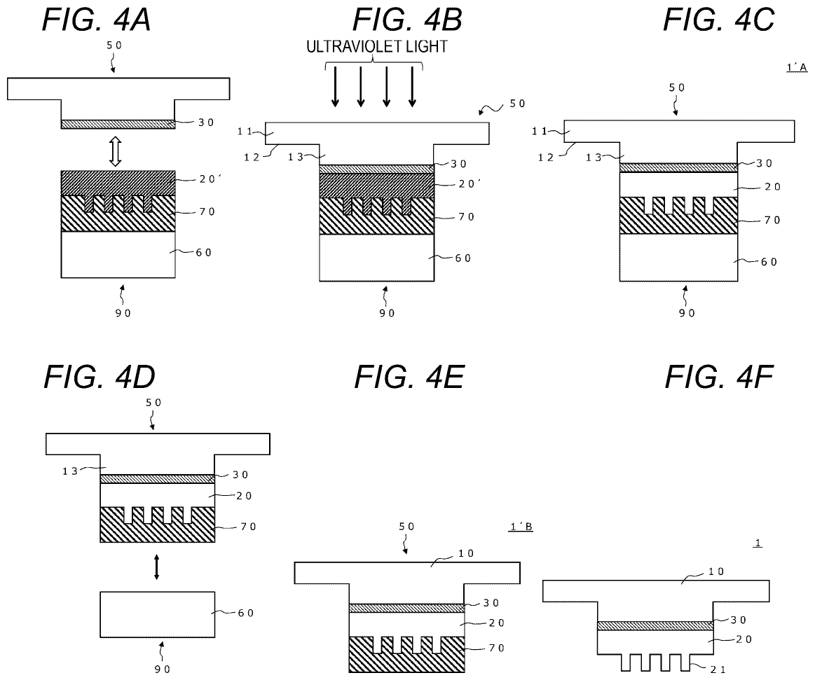

FIGS. 4A to 4F are cross-sectional views showing an example of a manufacturing method in which the first template portion 50 and the replication portion 20 are bonded with the adhesive film 30 sandwiched therebetween. As shown in FIG. 4A, the first template portion 50 is disposed such that the adhesive film 30 in the first template portion 50 and the replication material 20′ in the second template portion 90 face each other. Subsequently, the adhesive film 30 and the replication material 20′ are bonded to each other after position alignment. At this time, a space in which the first template portion 50 and the second template portion 90 are disposed is set in an atmosphere in which a reaction is inhibited when the space is irradiated with light. That is, when the replication material 20′ having a photo-radical polymerizable group is used, an atmosphere containing oxygen is set.

Next, as shown in FIGS. 4B and 4C, the replication material 20′ is irradiated with ultraviolet light through the first template portion 50 while the first template portion 50 is pressed. As a result, among regions irradiated with ultraviolet light, in a region in which the adhesive film 30 and the replication material 20′ are in contact, the adhesive film 30 and the replication material 20′ are bonded to be cured by a photoradical polymerization reaction. In addition, the replication material 20′ is cured to enter the replication portion 20. Therefore, in FIG. 4C, the template 1′A including the first template portion 50, the replication portion 20, the sacrificial layer 70, and the second substrate 60 is formed. It is desirable that a region corresponding to the mesa portion 13 in the first template portion 50 is irradiated with ultraviolet light, but generally, a wider range is irradiated with ultraviolet light than the region corresponding to the mesa portion 13. Since the mesa portion 13 protrudes from the base portion first surface 12, a periphery of the mesa portion 13 is filled with the atmosphere containing oxygen. Under the atmosphere containing oxygen, the photo-radical polymerizable group is difficult to cure, so that even when ultraviolet light is irradiated to the periphery of the mesa portion 13, the replication material 20′ is not cured in other regions that are not in contact with the adhesive film 30 and remains in a liquid state.

Then, as shown in FIG. 4D, the first template portion 50, the replication portion 20, and the sacrificial layer 70 are peeled off from the second substrate 60. At this time, fracture stress between the sacrificial layer 70 and the second substrate 60 is smaller than fracture stress between the adhesive film 30 and the replication portion 20, fracture stress of the replication portion 20, fracture stress between the replication portion 20 and the sacrificial layer 70, and fracture stress of the sacrificial layer 70. Therefore, when the first template portion 50, the replication portion 20, and the sacrificial layer 70 are peeled off from the second substrate 60, it is possible to perform peeling from a boundary between the sacrificial layer 70 and the second substrate 60 while preventing the replication portion 20 and the sacrificial layer 70 from being peeled off from the first template portion 50 and preventing the replication portion 20 and the sacrificial layer 70 from being broken. In addition, in regions other than the region corresponding to the mesa portion 13, since the replication material 20′ is not cured, the fracture stress of the replication portion 20 in the region corresponding to the mesa portion 13 is larger than the fracture stress of the replication material 20′ in the regions other than the region corresponding to the mesa portion 13. Therefore, in the replication portion 20 and the replication material 20′ during the peeling, the replication portion 20 is peeled off at a boundary between the region corresponding to the mesa portion 13 and other regions, and is separated from the second substrate 60. FIG. 4E shows the template 1′B formed after the second substrate 60 is peeled off in FIG. 4D.

Next, as shown in FIG. 4F, the sacrificial layer 70 is removed from the first template portion 50 and the replication portion 20 by performing wet etching. In FIG. 4E, the template 1′B including the template substrate 10, the adhesive film 30, the replication portion 20, and the sacrificial layer 70 is formed. That is, the sacrificial layer 70 is removed from the template 1′B to form the template 1. When the replication portion 20 and the sacrificial layer 70 are compared, etching rates are different for an agent used in wet etching, and the etching rate of the sacrificial layer 70 is higher than the etching rate of the replication portion 20. That is, the replication portion 20 is hardly removed by wet etching, and the sacrificial layer 70 is mainly removed. When the sacrificial layer 70 is removed from the template 1′B, the template 1 including the template substrate 10, the adhesive film 30 on the template substrate 10, and the replication portion 20 on the adhesive film 30 is formed. The pattern surface 21 having an uneven pattern in contact with a resist on a workpiece is provided on a surface of the replication portion 20 opposite to the surface in contact with the adhesive film 30 when the semiconductor device is subjected to an imprint process.

A method of removing the sacrificial layer 70 from the first template portion 50 and the replication portion 20 may be dry etching (a reactive ion etching (RIE)) in addition to wet etching. Even when dry etching is used, the etching rate of the sacrificial layer 70 is higher than the etching rate of the replication portion 20. A material of the sacrificial layer 70 and a material of the replication portion 20 may be selected under the above-described conditions.

As a comparative aspect, a circumstance when an uneven pattern corresponding to the uneven pattern formed on the pattern surface 21 of the replication portion 20 is provided on the second substrate 60 will be described. After a pattern corresponding to a desired pattern is formed on the second substrate 60, the replication portion 20 is formed by forming and curing the replication material 20′ on a pattern formation surface of the second substrate 60. Thereafter, the second substrate 60 is peeled off from the replication portion 20 after the replication portion 20 and the template substrate 10 are bonded to each other with the adhesive film 30 sandwiched therebetween.

In recent years, an aspect ratio of a pattern in a semiconductor device has been increased, and an aspect ratio of an uneven pattern provided on a template has also been increased in response to the increase in the aspect ratio of the pattern. Therefore, a pattern provided on the second substrate 60 or the sacrificial layer 70 corresponding to the uneven portion of the pattern to be provided on the template also enters a high aspect ratio. When peeling is performed between the second substrate 60 and the replication portion 20, a pattern including an uneven portion is formed on a surface to be peeled off. Therefore, when the replication portion 20 is peeled off from the second substrate 60 after the template substrate 10 and the replication portion 20 are bonded to each other, a projection portion in the pattern of the replication portion 20 may remain without being completely peeled off from a recess portion of the second substrate 60 and the pattern may enter to be formed poorly.

In the present embodiment, in the template 1, the sacrificial layer 70 is removed by etching before being used in the imprint process. That is, when the sacrificial layer 70 is removed from the template substrate 10, the replication portion 20, and the adhesive film 30, wet etching or dry etching using an etching ratio between the sacrificial layer 70 and the replication portion 20 is performed to remove the sacrificial layer 70. When the sacrificial layer 70 is removed, a load applied to the pattern formed on the pattern surface 21 of the replication portion 20 is reduced, so that a pattern defect can be reduced. In addition, the sacrificial layer 70 is provided between the second substrate 60 and the replication portion 20 to form a pattern on the sacrificial layer 70. Then, peeling is performed between the sacrificial layer 70 and the second substrate 60. Since the pattern is not provided between the sacrificial layer 70 and the second substrate 60, a pattern defect when the second substrate 60 is peeled off can be reduced. When the sacrificial layer 70 is removed from the template substrate 10, the replication portion 20, and the adhesive film 30, a projection portion in the pattern of the replication portion 20 is prevented from remaining in the recess portion of the sacrificial layer 70 by performing etching. Therefore, it is possible to reduce the pattern defect. In addition, since the number of templates having a pattern in which a defect has occurred is reduced as compared to that in the comparative aspect during manufacturing of the template, a manufacturing cost of the template can be reduced.

### Second Embodiment

Since a configuration of the template 1 according to a second embodiment is the same as the configuration of the template 1 according to the first embodiment, so that the description thereof will not be shown. Further, the first template portion 50 used in the present embodiment may have the same configuration as that of the template 1 according to the first embodiment, so that the description thereof will not be shown.

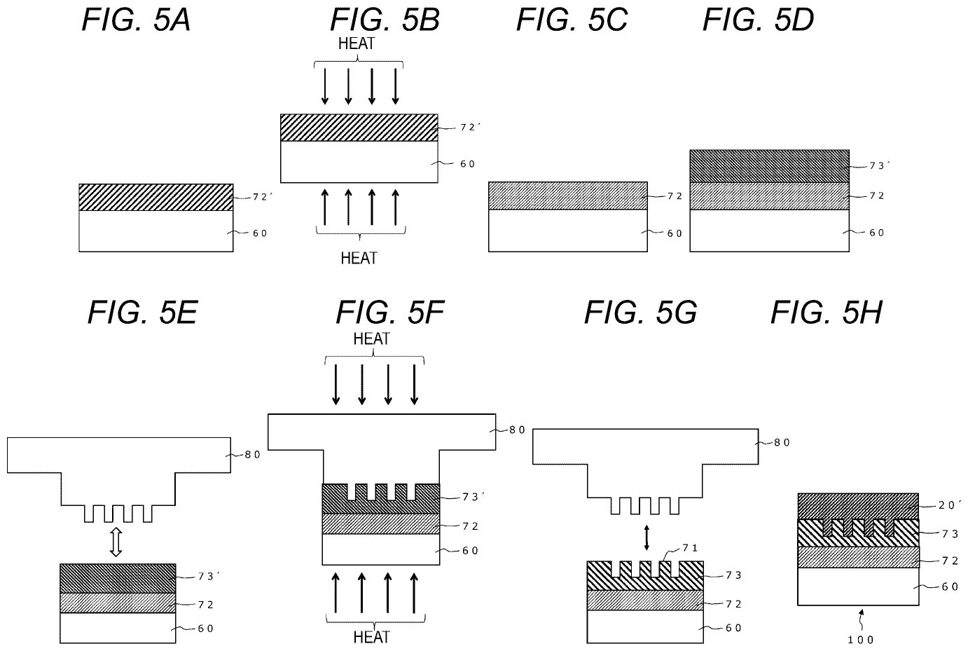

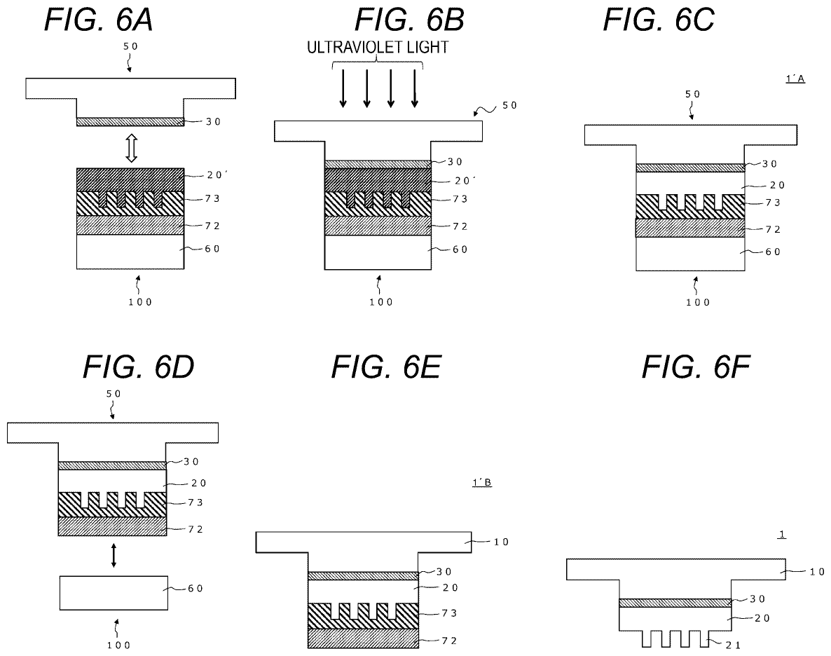

FIGS. 5A to 6F are cross-sectional views schematically showing the example of the procedure of the method of manufacturing the template 1 according to the second embodiment. Here, a circumstance when the replication material 20′, which is the adhesive film 30 and the replication portion 20 before curing, contains a photocurable material having a photo-radical polymerizable group will be described.

FIGS. 5A to 5H are cross-sectional views showing the example of the method of manufacturing the replication portion 20 bonded to the template substrate 10 with the adhesive film 30 sandwiched therebetween. As shown in FIG. 5A, first, a first sacrificial material 72′ is formed on the second substrate 60. The second substrate 60 is, for example, a silicon substrate. The first sacrificial material 72′ is formed by, for example, a spin coating method or a sputtering method. The first sacrificial material 72′ may use a material cured by ultraviolet light or heat. When the first sacrificial material 72′ is cured by ultraviolet light or heat, the first sacrificial material 72′ enters a first sacrificial layer 72 after the curing.

For example, the same material with the material shown as an example as the replication material 20′ may be used as the first sacrificial material 72′. Meanwhile, it is preferable for the first sacrificial layer 72 to use the first sacrificial material 72′, which has a higher etching rate than that of the replication portion 20 with respect to the material used for etching.

For example, when the first sacrificial material 72′ is a material cured by ultraviolet light, the first sacrificial material 72′ may be a transparent resin such as an acrylic, an epoxy, a polyamide, or a polyimide containing an ultraviolet light polymerization initiator. The first sacrificial material 72′ contains a material having a reactive group for curing by ultraviolet light. For example, as the reactive group cured by ultraviolet light, the material is a material containing a photo-radical polymerizable group having at least one reactive moiety selected from an acryloyl group, a methacryloyl group, and a vinyl ether group, or a photo-cation polymerizable group having at least one reactive moiety selected from an epoxy group and an oxetanyl group. In the material that reacts with and is cured by ultraviolet light, the first sacrificial layer 72 hardly shrinks during the curing.

In addition to the above-described material containing the ultraviolet light polymerization initiator, a resin that reacts with heat to be cured may be used as the first sacrificial material 72′. A thermosetting resin is, for example, a novolac resin or a vinyl resin. When the first sacrificial layer 72 contains a thermosetting resin, the first sacrificial material 72′ contains a reactive group for curing by heat, and may not contain a reactive group that reacts with ultraviolet light. Further, when a thermosetting resin is used as the first sacrificial material 72′, the first sacrificial layer 72 may shrink during the curing, so that it is necessary to pre-calculate a shrinkage rate before the curing.

Alternatively, a material capable of maintaining a shape without being cured by ultraviolet light or heat may be used as the first sacrificial material 72′. The material capable of maintaining a shape is a material having a hardness such that a pattern is maintainable even after the master template 80 is peeled off when the pattern is formed on the first sacrificial material 72′ in a step to be described later. In this case, it is not necessary to perform curing with ultraviolet light or heat, and the first sacrificial material 72′ also functions as the first sacrificial layer 72.

Hereinafter, a novolac resin having a reactive moiety cured by heat will be described as an example of the first sacrificial material 72′ and the first sacrificial layer 72.

Next, as shown in FIGS. 5B and 5C, the first sacrificial material 72′ is heated to be cured to form the first sacrificial layer 72.

Next, as shown in FIG. 5D, a second sacrificial material 73′ is formed on the first sacrificial layer 72. The second sacrificial material 73′ is formed by, for example, a spin coating method or a sputtering method. For example, it is preferable for the second sacrificial material 73′ to use a material having a higher etching rate than that of the replication portion 20, with respect to a material used for etching of a second sacrificial layer 73 after the curing. In addition, it is preferable that a height of the second sacrificial layer 73 in the stacking direction is higher than a height of the recess portion in the pattern formed in the second sacrificial layer 73.

When the second sacrificial material 73′ is cured by ultraviolet light or heat, the second sacrificial material 73′ enters the second sacrificial layer 73 after the curing. Meanwhile, it is preferable to use a material different from a material selected as the first sacrificial material 72′. In addition, it is preferable to use a material as the second sacrificial material 73′ in which fracture stress of the second sacrificial layer 73 is at least greater than fracture stress between the second substrate 60 and the first sacrificial layer 72 and fracture stress of the first sacrificial layer 72.

When the second sacrificial layer 73 contains a thermosetting resin, the second sacrificial material 73′ contains a reactive group for curing by heat, and may not contain a reactive group that reacts with ultraviolet light. Further, when a thermosetting resin is used as the second sacrificial material 73′, the second sacrificial layer 73 may shrink during the curing, so that it is necessary to pre-calculate a shrinkage rate before the curing. When a thermosetting resin is used as the second sacrificial material 73′, while a shrinkage rate is in consideration, the second sacrificial material 73′ is formed such that a height of the second sacrificial layer 73 in the stacking direction is higher than a height of a recess portion of a pattern formed on the second sacrificial layer 73 in the stacking direction.

Hereinafter, a circumstance when a novolac resin having a reactive moiety cured by heat is used as the second sacrificial material 73′ and the second sacrificial layer 73 will be described as an example. A circumstance will be described, when the novolac resin used as the second sacrificial material 73′ and the second sacrificial layer 73 has a different type from that of the novolac resin contained in the first sacrificial material 72′ and the first sacrificial layer 72.

As shown in FIGS. 5E and 5F, the master template 80 is pressed against the second sacrificial material 73′ after position alignment. The master template 80 has the same pattern as that of an uneven pattern on the pattern surface of the replication portion 20. Heat is applied to the master template 80 while being pressed against the second sacrificial material 73′ to cure the second sacrificial material 73′.

As shown in FIG. 5G, the second sacrificial material 73′ is cured by heated to enter the second sacrificial layer 73. After the second sacrificial layer 73 is formed, when the master template 80 is removed, the patterned resist 71 is formed on the second sacrificial layer 73. The patterned resist 71 is a pattern corresponding to the uneven pattern formed on the pattern surface 21 in the replication portion 20.

Next, as shown in FIG. 5H, the replication material 20′ having a liquid state photo-radical polymerizable group is formed on an entire surface of the second sacrificial layer 73 by a spin coating method. The replication material 20′ is formed on the entire surface of the second sacrificial layer 73 with a substantially uniform thickness while a recess portion of the second sacrificial layer 73 is embedded with the replication material 20′. The second substrate 60, the first sacrificial layer 72, the second sacrificial layer 73, and the replication material 20′ (or the replication portion 20) are referred to as a third template portion 100.

FIGS. 6A to 6F are cross-sectional views showing an example of a manufacturing method in which the first template portion 50 and the replication portion 20 are bonded with the adhesive film 30 sandwiched therebetween. FIGS. 6A to 6C may have the same procedure as that of the first embodiment, so that the description thereof will not be shown. That is, FIGS. 6A to 6C show the same method as that in FIGS. 4A to 4C, and the replication material 20′ is cured by irradiation with ultraviolet light to enter the replication portion 20. Therefore, in FIG. 6C, the template 1′A including the first template portion, the replication portion 20, the sacrificial layer 70, and the second substrate 60 is formed.

Next, as shown in FIG. 6D, the first template portion 50, the replication portion 20, the first sacrificial layer 72, and the second sacrificial layer 73 are peeled off from the second substrate 60. At this time, fracture stress between the first sacrificial layer 72 and the second substrate 60 and fracture stress of the first sacrificial layer 72 are smaller than fracture stress between the adhesive film 30 and the replication portion 20, fracture stress of the replication portion 20, fracture stress between the replication portion 20 and the second sacrificial layer 73, and fracture stress of the second sacrificial layer 73. The fracture stress between the first sacrificial layer 72 and the second sacrificial layer 73 may be greater than the fracture stress between the first sacrificial layer 72 and the second substrate 60, and the fracture stress of the first sacrificial layer 72. Therefore, when the first template portion 50, the replication portion 20, the first sacrificial layer 72, and the second sacrificial layer 73 are peeled off from the second substrate 60, the replication portion 20, the first sacrificial layer 72, and the second sacrificial layer 73 are prevented from being peeled off from the first template portion 50. In addition, it is possible to perform peeling in a boundary between the first sacrificial layer 72 and the second substrate 60 or the first sacrificial layer 72 while the replication portion 20 and the second sacrificial layer 73 are prevented from being broken. That is, the peeling is not limited to the boundary between the first sacrificial layer 72 and the second substrate 60, and may occur in the first sacrificial layer 72 or may occur between the first sacrificial layer 72 and the second sacrificial layer 73. By providing the first sacrificial layer 72, it is possible that the second substrate 60 is peeled off from the first template portion 50, the replication portion 20, the first sacrificial layer 72, and the second sacrificial layer 73 in the first sacrificial layer 72 or at the boundary between the first sacrificial layer 72 and the second substrate 60. In this case, it is possible to further reduce a load when the replication portion 20 and the second sacrificial layer 73 having the pattern surface are peeled off. In addition, in regions other than the region corresponding to the mesa portion 13, since the replication material 20′ is not cured, the fracture stress of the replication portion 20 in the region corresponding to the mesa portion 13 is larger than the fracture stress of the replication material 20′ in the regions other than the region corresponding to the mesa portion 13. Therefore, in the replication portion 20 and the replication material 20′ during the peeling, the replication portion 20 is peeled off from the second substrate 60 at a boundary between the region corresponding to the mesa portion 13 and other regions.

Next, as shown in FIGS. 6E and 6F, the first sacrificial layer 72 and the second sacrificial layer 73 are removed from the template substrate 10, the adhesive film 30, and the replication portion 20 by performing wet etching. When peeling occurs between the first sacrificial layer 72 and the second sacrificial layer 73, the second sacrificial layer 73 is removed from the template substrate 10, the adhesive film 30, and the replication portion 20 by wet etching.

In FIG. 6E, the template 1′B including the template substrate 10, the adhesive film 30, the replication portion 20, the first sacrificial layer 72, and the second sacrificial layer 73 is formed. That is, the first sacrificial layer 72 and the second sacrificial layer 73 are removed from the template 1′B to form the template 1. When the replication portion 20 is compared with the first sacrificial layer 72 and the second sacrificial layer 73, etching rates for the agent used in wet etching are different from each other, and the etching rates of the first sacrificial layer 72 and the second sacrificial layer 73 are higher than the etching rate of the replication portion 20. That is, the replication portion 20 is hardly removed by wet etching, and the first sacrificial layer 72 and the second sacrificial layer 73 are mainly removed from the template 1′B. When the first sacrificial layer 72 and the second sacrificial layer 73 are removed, the template 1 including the template substrate 10, the adhesive film 30 on the template substrate 10, and the replication portion 20 on the adhesive film 30 is formed. The pattern surface 21 having an uneven pattern in contact with a resist on a workpiece is provided on a surface of the replication portion 20 opposite to the surface in contact with the adhesive film 30 when a semiconductor storage device is subjected to an imprint process.

A method of removing the first sacrificial layer 72 and the second sacrificial layer 73 from the first template portion 50 and the replication portion 20 may be dry etching in addition to wet etching. Even when dry etching is used, the etching rate of the sacrificial layer 70 is higher than the etching rate of the replication portion 20. Under the above conditions, materials of the first sacrificial layer 72, the second sacrificial layer 73, and the replication portion 20 may be selected.

Also in the present embodiment, a pattern defect can be prevented in the same manner as that in the first embodiment. In particular, by performing peeling using the first sacrificial layer 72 and the second sacrificial layer 73, the load applied to the pattern can be further reduced, and an effect of reducing the pattern defect can be further increased. In addition, the sacrificial layer provided between the second substrate 60 and the replication portion 20 is not limited to two layers, and a plurality of layers of three or more layers may be provided.

### Third Embodiment

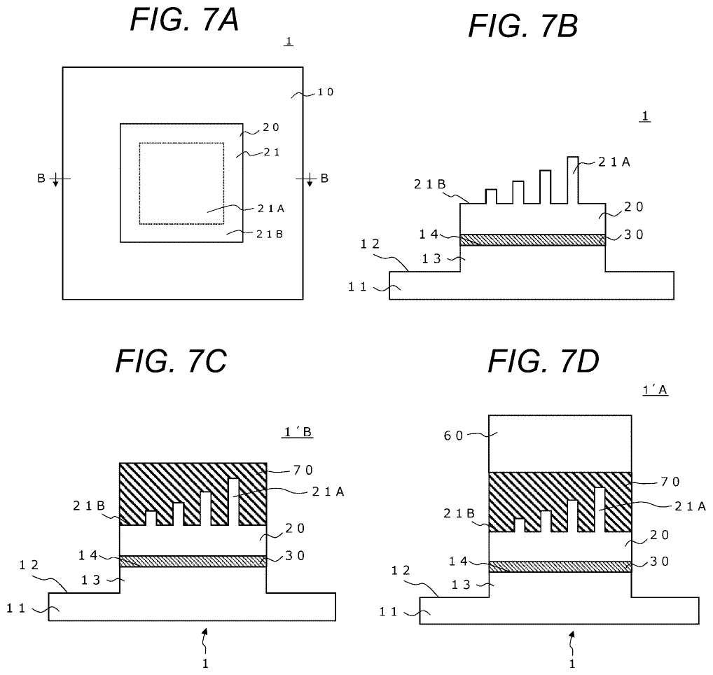

FIGS. 7A to 7D are views schematically showing an example of a configuration of the template 1 according to a third embodiment. FIG. 7A is an upper surface view, and FIG. 7B is a cross-sectional view taken along line B-B in FIG. 7A. In addition, FIG. 7C is a cross-sectional view schematically showing an example in which the sacrificial layer 70 is formed on the template 1, and FIG. 7D is a cross-sectional view schematically showing an example in which the sacrificial layer 70 and the second substrate 60 are formed on the template 1.

When the template 1 according to the third embodiment is compared with the template 1 according to the first embodiment, heights of patterns, that is, lengths of a plurality of projection portions formed in the pattern arrangement region 21A are different.

Since other configurations of the template 1 according to the third embodiment may be the same as those of the template 1 according to the first embodiment, the description thereof will not be shown.

A procedure of a method of manufacturing the template 1 according to the third embodiment shown in FIGS. 7A to 7D may be the same as the procedures of the methods of manufacturing the template 1 according to the first embodiment and the second embodiment. That is, for example, it is possible to manufacture the template 1 according to the third embodiment by the manufacturing method as shown in FIGS. 2A to 4F or FIGS. 5A to 6F.

In the template 1 according to the third embodiment, the pattern surface 21 is provided on a surface opposite to a surface of the replication portion 20 in contact with the adhesive film 30. The pattern arrangement region 21A provided on the pattern surface 21 is disposed with a pattern such as a device and wiring to be formed on the workpiece. In the pattern arrangement region 21A, at least a part of the formed plurality of projection portions have respectively different lengths, and a longer projection portion is easily broken as compared with a shorter projection portion during the peeling. The template 1 according to the third embodiment is also manufactured by the manufacturing method as described in the first embodiment and the second embodiment. Therefore, since the sacrificial layer 70 is removed from the replication portion 20 by wet etching or dry etching, it is possible to prevent the projection portion formed in the replication portion 20 from being broken during template manufacturing. Also in the present embodiment, a pattern defect can be reduced as in the first embodiment and the second embodiment.

### Fourth Embodiment

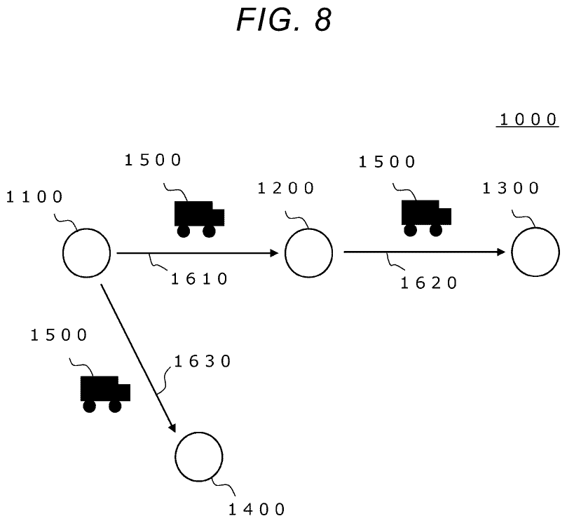

FIG. 8 is a diagram showing an example of movement such as conveyance of the template 1′A or the template 1′B as described in the first to third embodiments.

The template 1′A according to the present embodiment is shown in FIGS. 1D and 4C showing the template of the first embodiment, in FIG. 6C showing the template of the second embodiment, and in FIG. 7D showing the template of the third embodiment. Further, the template 1′B according to the present embodiment is shown in FIGS. 1C and 4E showing the template of the first embodiment, in FIG. 6E showing the template of the second embodiment, and in FIG. 7C showing the template of the third embodiment.

In a certain region 1000, manufacturing bases 1100, 1200, 1300, and 1400 are present. The manufacturing bases 1100 to 1400 may be manufacturing bases belonging to the respectively same unit or may be manufacturing bases belonging to respectively different units. The unit according to the present embodiment refers to, for example, an independent entity such as a company, a university, or a research institute. Therefore, the manufacturing bases 1100 to 1400 are, for example, different buildings or areas in the same company when the manufacturing bases 1100 to 1400 belong to the respectively same unit. In addition, when the manufacturing bases 1100 to 1400 belong to the respectively different units, for example, the units may be respectively different companies and may be trading partners with each other.

A conveyance device 1500 is capable of accommodating and moving the template 1′A or the template 1′B. The conveyance device 1500 may be, for example, a vehicle such as a truck.

Transport paths 1610 to 1630 (hereinafter, may also be referred to as a conveyance path 1600) are paths connecting the manufacturing bases 1100 to 1400, and in which the conveyance device 1500 is passable. The conveyance path 1600 may be, for example, a road, a railway, or the like.

Hereinafter, an example of a conveyance of the template 1′A or the template 1′B will be described.

First, the template 1′A is manufactured at the manufacturing base 1100.

Next, the template 1′A is conveyed from the manufacturing base 1100 to the manufacturing bases 1200 and 1400. For example, the conveyance device 1500 is used for the conveyance, and the template 1′A is accommodated in the conveyance device 1500. The conveyance device 1500 accommodating the template 1′A respectively conveys the template 1′A to the manufacturing bases 1200 or 1400 through the conveyance path 1610 or the conveyance path 1630, respectively.

After the conveyance of the template 1′A, the second substrate 60 is peeled off at the manufacturing bases 1200 and 1400. Therefore, the template 1′B is manufactured in the manufacturing bases 1200 and 1400. In addition, in the manufacturing base 1400, after the second substrate 60 is peeled off, the sacrificial layer 70 or the first sacrificial layer 72 and the second sacrificial layer 73 may be removed from the first template portion 50 and the replication portion 20 by etching. Therefore, the template 1 may be manufactured from the template 1′B at the manufacturing base 1400. The template 1 is shown, for example, in FIGS. 1A to 1D, 4F, 6F, and 7A to 7D. At the manufacturing base 1400, the template 1 may be used, for example, when an imprint process in manufacturing the semiconductor device to be described later is performed.

Further, the template 1′B may be conveyed from the manufacturing base 1200 to the manufacturing base 1300. For example, the conveyance device 1500 is used for the conveyance, and the template 1′B is accommodated in the conveyance device 1500. The conveyance device 1500 accommodating the template 1′B conveys the template 1′B to the manufacturing base 1300 through the conveyance path 1620. At the manufacturing base 1300, in the template 1′B, the sacrificial layer 70 or the first sacrificial layer 72 and the second sacrificial layer 73 may be removed from the first template portion 50 and the replication portion 20 by etching. That is, the template 1 may be manufactured from the template 1′B at the manufacturing base 1300. The template 1 is shown, for example, in FIGS. 1A to 1D, 4F, 6F, and 7A to 7D. At the manufacturing base 1300, the template 1 may be used, for example, when the imprint process in manufacturing the semiconductor device to be described later is performed.

When the conveyance is performed from the manufacturing base 1100 to the manufacturing base 1300 or when the conveyance is performed from the manufacturing base 1100 to the manufacturing base 1400, the conveyance device 1500 accommodates the template 1′A or the template 1′B. In the template 1′A, the second substrate 60, the sacrificial layer 70, the first sacrificial layer 72, and the second sacrificial layer 73 cover the pattern surface 21 in the replication portion 20. In addition, also in the template 1′B, the sacrificial layer 70, the first sacrificial layer 72, and the second sacrificial layer 73 cover the pattern surface 21 of the replication portion 20. Therefore, the second substrate 60, the sacrificial layer 70, the first sacrificial layer 72, and the second sacrificial layer 73 are capable of protecting the pattern formed on the pattern surface 21, and can reduce damage such as an impact received by the pattern formed on the template 1 during conveyance. That is, in the template 1, it is possible to reduce a pattern defect caused by the conveyance.

### Fifth Embodiment

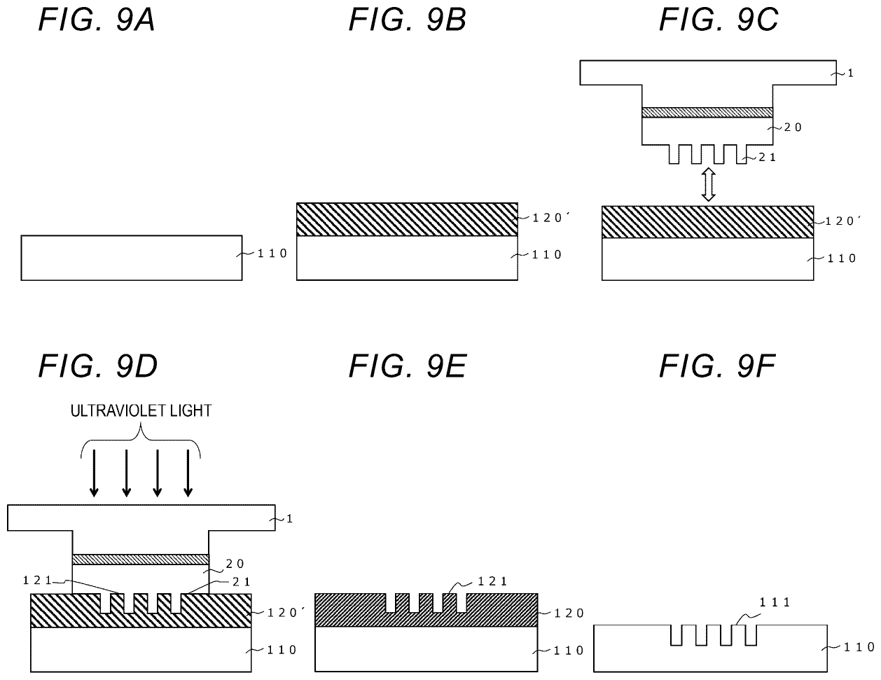

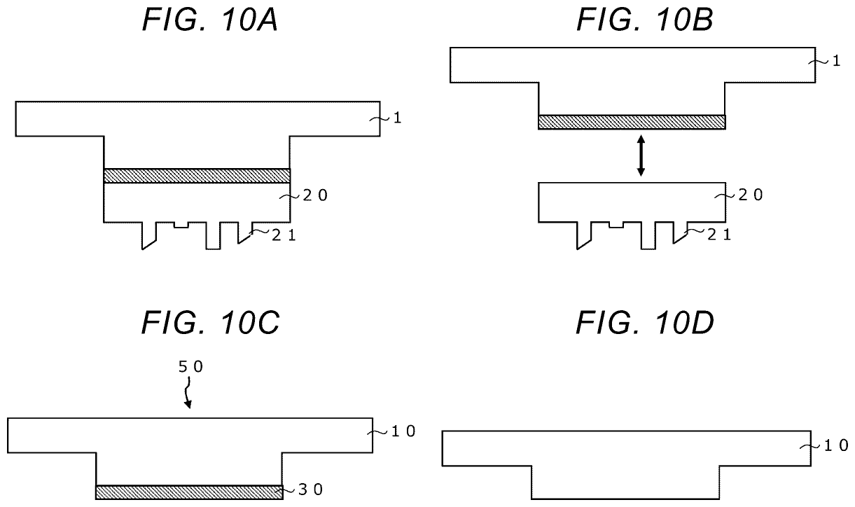

A method of manufacturing a semiconductor device using the template 1 according to the first to third embodiments will be described. FIGS. 9A to 9F are cross-sectional views schematically showing an example of a procedure of a method of manufacturing a semiconductor device according to a fifth embodiment. FIGS. 10A to 10D are cross-sectional views schematically showing an example of the procedure of the method of remanufacturing the template 1 according to the fifth embodiment.

First, as shown in FIG. 9A, a workpiece 110 is prepared. The workpiece 110 is, for example, a semiconductor substrate such as a silicon substrate, a semiconductor film formed on the semiconductor substrate, a conductive film, an insulating film, and the like.

Next, as shown in FIG. 9B, a resist 120′ (or resist layer 120′) is dropped onto a shot region of the workpiece 110. The resist 120′ may be, for example, a photocurable resin containing a reactive group that reacts with light, and is cured by irradiation with ultraviolet light when the photocurable resin is used, so that a resist 120 (or resist layer 120) to be described later is formed. The resist 120′ may be dropped onto the workpiece 110 by, for example, an inkjet method, or may be applied to an entire surface of the workpiece 110 by a spin coating method.

As shown in FIG. 9C, in the template 1, a rough position alignment between the template 1 and the workpiece 110 is performed in a state where the replication portion 20 having the pattern surface 21 is allowed to face the workpiece 110.

Thereafter, as shown in FIG. 9D, at least one of the template 1 and the workpiece 110 is moved until the replication portion 20 comes into contact with the resist 120′. Then, more precise position alignment is performed between the template 1 and the workpiece 110. After a recess portion of the template 1 is filled with the resist 120′, the resist 120 is formed by curing the resist 120′ by irradiating the resist 120′ with ultraviolet light. Further, a patterned resist 121 having a plurality of uneven portions is formed on the resist 120. Next, as shown in FIG. 9E, the template 1 is peeled off from the resist 120.

Thereafter, as shown in FIG. 9F, the workpiece 110 is processed by anisotropic etching such as RIE using the patterned resist 121 as a mask. By repeating such a process, an upper surface of the workpiece 110 is processable into a desired pattern 111, and a semiconductor device having the pattern 111 is manufactured.

At this time, when a process is repeatedly executed, in which the template 1 is peeled off from the resist 120 after the template 1 is pressed against the resist 120′ on the workpiece 110 many times to cure the resist 120′, as shown in FIG. 10A, the pattern on the pattern surface 21 of the replication portion 20 may be damaged. When the imprint process is performed using the template 1 in which the pattern is damaged, the desired patterned resist 121 may not be formed. In such a case, in the template 1 of the present embodiment, it is possible to remove the damaged replication portion 20. The new replication portion 20 can be easily reproduced by forming the new replication portion 20 on the mesa portion 13 of the template substrate 10 with the adhesive film 30 sandwiched therebetween.

First, as shown in FIG. 10B, the damaged replication portion 20 of the template 1 is peeled off by cleaning. As a cleaning solution used for cleaning, for example, it is possible to use a sulfuric acid hydrogen peroxide solution, which is a mixed solution of sulfuric acid and hydrogen peroxide water, but the cleaning solution may be appropriately changed depending on a type and a material of a resin contained in the replication portion 20. By peeling off the replication portion 20, the first template portion 50 in which the template substrate 10 and the adhesive film 30 remain is obtained as shown in FIG. 10C. At this time, as a method of removing the replication portion 20, the replication portion 20 may be physically peeled off from the adhesive film 30.

Thereafter, as shown in FIG. 10D, the adhesive film 30 is removed by wet etching or the like. Thereafter, the template 1 is reproduced by forming the new replication portion 20 on the mesa portion 13 of the template substrate 10, as in the method of manufacturing the template 1 shown in FIGS. 3A to 4F (the first embodiment) and FIGS. 5A to 6F (the second embodiment). The reproduced template 1 is used in the method of manufacturing a semiconductor device shown in FIGS. 9A to 9F.

Also in the present embodiment, as in the first to third embodiments, a pattern defect of the template can be reduced, and further, a pattern defect of the semiconductor device manufactured using the template can also be reduced.

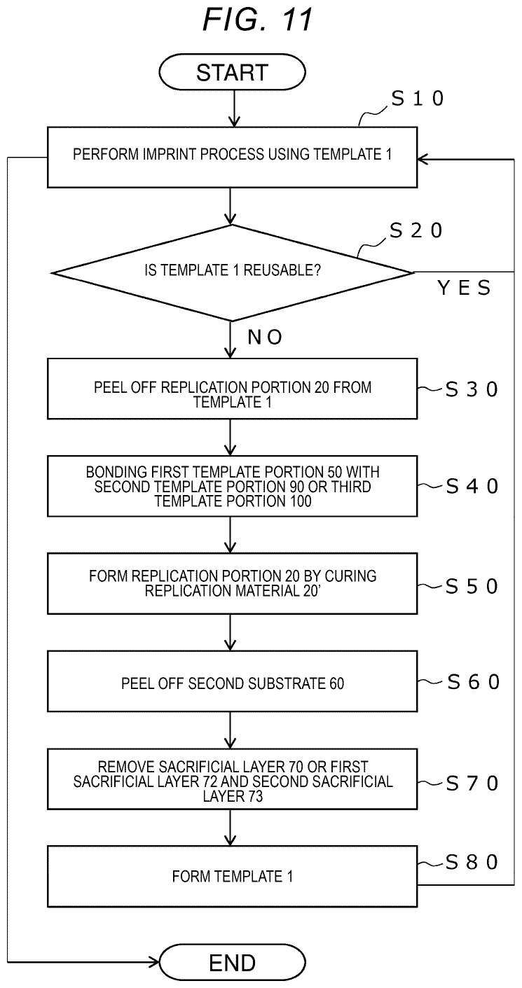

FIG. 11 is a flowchart showing an example of the procedure of the method of remanufacturing the template 1 according to the fifth embodiment.

First, an imprint process of a semiconductor device is performed using the template 1 having a replication portion including a pattern surface (S10). Then, it is determined whether the template 1 is in a state where the template 1 is usable again for the imprint process after the imprint process (S20). Specifically, the pattern formed in the replication portion 20 of the template 1 is checked for defects or the like.

When the template is reusable (YES in S20), the imprint process of the semiconductor device is performed again by using the template 1 (S10).

For example, when the template 1 is not reusable due to a defect in the pattern of the template 1 (NO in S20), the damaged replication portion 20 of the template 1 is peeled off by cleaning (S30). At this time, the remaining adhesive film 30 may be removed from the template substrate 10 by wet etching or the like in the template 1.

The adhesive film 30 is formed again on the template substrate 10 by a vapor deposition method or the like. Then, as shown in FIG. 4A or FIG. 6A, the first template portion 50 including the template substrate 10 and the adhesive film 30 and the second template portion 90 or the third template portion 100 are bonded to each other (S40). At this time, the adhesive film 30 of the first template portion 50 and the replication material 20′ of the second template portion 90 or the third template portion 100 are bonded to face each other. The replication material 20′ is cured by irradiation with ultraviolet light or heating to form the replication portion 20 (S50). After the formation of the replication portion 20, the second substrate 60 is peeled off from the first template portion 50, the replication portion 20, and the sacrificial layer 70 (the first sacrificial layer 72 and the second sacrificial layer 73) (S60).

After the second substrate 60 is peeled off, the sacrificial layer 70 (the first sacrificial layer 72 and the second sacrificial layer 73) is removed from the first template portion 50 and the replication portion 20 by performing wet etching or dry etching (S70). At this time, the sacrificial layer 70 (the first sacrificial layer 72 and the second sacrificial layer 73) has a higher etching rate than that of the replication portion 20 with respect to the material used for etching. Therefore, the sacrificial layer 70 (first sacrificial layer 72, second sacrificial layer 73) is removable while the replication portion 20 remains, and the template 1 including the template substrate 10, the adhesive film 30, and the replication portion 20 is reproduced (S80).

The reproduced template 1 is usable again for the imprint process of the semiconductor device.

In the present embodiment, an imprint process is performed using the template 1 in which the resin-made replication portion 20 on which a pattern is formed is bonded to the mesa portion 13 on the template substrate 10. When the replication portion 20 is damaged as a result of a repetition of the imprint process, the replication portion 20 is removed, and the new replication portion 20 is formed on the mesa portion 13 to reproduce the template 1.

When the template configured entirely with quartz glass is damaged, the entire template enters to be discarded. However, in the present embodiment, it is sufficient that the replication portion 20 is discarded, the replication portion 20 is manufactured again, and the replication portion 20 is bonded to the template substrate 10 with the adhesive film 30 sandwiched therebetween. Therefore, in the present embodiment, the template 1 can be manufactured at a low cost as compared with a manufacturing cost when the template configured entirely with quartz glass is used.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method of manufacturing a template, comprising:
forming a sacrificial layer on a substrate;
forming a first pattern on a surface of the sacrificial layer opposite to a surface of the sacrificial layer in contact with the substrate;
forming a replication material layer on a surface of the first pattern of the sacrificial layer;
bonding, to a template substrate, a surface of the replication material layer opposite to a surface of the replication material layer in contact with the sacrificial layer;
curing the replication material layer to form a replication portion having a second pattern corresponding to the first pattern; and
removing the substrate from the sacrificial layer to provide the template including the template substrate and the replication portion.

2. The method according to claim 1, further comprising:
removing the sacrificial layer from the template.

3. The method according to claim 2, wherein
the sacrificial layer is removed by wet etching or dry etching.

4. The method according to claim 1, wherein
a material of the sacrificial layer is a resin cured by a reaction with ultraviolet light or heat.

5. The method according to claim 1, further comprising:
forming a second sacrificial layer on a second substrate;
forming a third pattern on a surface of the second sacrificial layer opposite to a surface of the second sacrificial layer in contact with the second substrate;
forming a second replication material layer on the third pattern of the second sacrificial layer;
removing the replication portion having the second pattern from the template substrate;
in response to removing the replication portion, bonding, to the template substrate, a surface of the second replication material layer opposite to a surface of the second replication material layer in contact with the second sacrificial layer;
curing the second replication material layer to form a second replication portion having a fourth pattern; and
removing the second substrate from the second sacrificial layer to provide the template including the template substrate and the second replication portion.

6. The method according to claim 5, wherein
the third pattern is the same as the first pattern, and
the fourth pattern is the same as the second pattern.

7. The method according to claim 5, further comprising:
removing the second sacrificial layer from the template.

8. The method according to claim 7, wherein
the second sacrificial layer is removed by wet etching or dry etching.

9. The method according to claim 8, wherein
a material of the second sacrificial layer is a resin cured by a reaction with ultraviolet light or heat.

10. The method according to claim 1, further comprising:
removing the sacrificial layer from the template;
preparing a semiconductor substrate on which a resist layer is formed;
pressing the template and the semiconductor substrate such that a surface on which the resist layer is formed on the semiconductor substrate and the replication portion of the template face each other;
curing the resist layer; and
removing the template from the resist layer.

11. The method according to claim 10, wherein
the sacrificial layer is removed by wet etching or dry etching.

12. The method according to claim 11, wherein
a material of the sacrificial layer is a resin cured by a reaction with ultraviolet light or heat.

13. A template, comprising:
a template substrate;
a replication portion provided on the template substrate and having a first pattern; and
a sacrificial layer provided on the replication portion, the sacrificial layer having a second pattern corresponding to the first pattern of the replication portion and having a higher etching rate than that of the replication portion.

14. The template according to claim 13, wherein
the template is usable in an imprint process by removing the sacrificial layer.

15. The template according to claim 14, wherein
the sacrificial layer is removable by wet etching or dry etching.

16. The template according to claim 15, wherein
a material of the sacrificial layer is a cured resin.

17. The template according to claim 13, further comprising:
a substrate provided on the sacrificial layer, wherein
the substrate is removable from the sacrificial layer before the template is used in an imprint process.
